(19) United States
(12) Patent Application Publication
(10) Pub. No.: US 2025/0344335 A1
(43) Pub. Date: Nov. 6, 2025

(54) SLIDE RAIL LOCKING DEVICE

(71) Applicant: FOSITEK CORPORATION, New Taipei City (TW)

(72) Inventors: Hsu-Hong YAO, New Taipei City (TW); Hsiu-Fan Ho, New Taipei City (TW); Hao-Ping Wang, New Taipei City (TW); Pao-Ting Chen, New Taipei City (TW)

(73) Assignee: FOSITEK CORPORATION, New Taipei City (TW)

(21) Appl. No.: 19/022,245

(22) Filed: Jan. 15, 2025

Related U.S. Application Data
(63) Continuation-in-part of application No. 18/775,552, filed on Jul. 17, 2024.

(30) Foreign Application Priority Data
May 3, 2024 (TW) 113116494
Sep. 24, 2024 (TW) 113136239

(51) Int. Cl. H05K 7/14

(52) U.S. Cl. CPC H05K 7/1489; H05K 7/1405

(57) ABSTRACT

A slide rail locking device includes a base unit, a locking member, and a driving member, and is adapted to be disposed on a slide rail that includes an outer rail and an inner rail. The base unit includes a base, an inner support frame, and an outer frame that has an outer connecting portion and an engaging portion. The base has a strength that is greater than a strength of the inner rail. The inner support frame and the base cooperatively define a moving slot. The locking member has a locking portion that separably engages the engaging portion of the outer frame. The driving member is movably disposed in the moving slot, and is operable to move along the moving slot to urge the locking member to rotate such that the locking portion of the locking member is disengaged from the engaging portion of the outer frame.

### CROSS-REFERENCE TO RELATED APPLICATION

This is a continuation-in-part application of U.S. patent application Ser. No. 18/775,552, filed on Jul. 17, 2024, which claims priority to Taiwanese Invention patent application Ser. No. 11/311,6494, filed on May 3, 2024. The aforesaid applications are incorporated by reference herein in their entirety.

This continuation-in-part application claims priority to Taiwanese Invention patent application Ser. No. 11/313,6239, filed on Sep. 24, 2024, the entire disclosure of which is incorporated by reference herein.

### FIELD

The present disclosure relates to a locking device, and more particularly to a slide rail locking device.

### BACKGROUND

A conventional slide rail locking device is adapted to be mounted to a slide rail. The slide rail is disposed on a server rack cabinet, and includes an outer rail that is fixedly mounted to the server rack cabinet, and an inner rail that is slidable relative to the outer rail and that is connected to a server. The slide rail locking device is disposed between the inner rail and the outer rail, and is used for preventing the inner rail from sliding out of the outer rail. The slide rail locking device includes an outer connecting frame that is fixedly connected to the outer rail, and a locking member that is pivotably connected to the inner rail and that separably engages the outer connecting frame. When the locking member engages the outer connecting frame, the inner rail is prevented from sliding out of the outer rail. When the locking member is disengaged from the outer connecting frame, the inner rail is movable relative to the outer rail and thus the server may be removed from the server rack cabinet for maintenance. However, the locking member of the conventional slide rail locking device is pivotably connected to the inner rail. Because the inner rail is generally long and made of steel with a relatively low hardness, deformation of the inner rail may easily cause the locking member to be unable to pivot smoothly or engage the outer connecting frame, and hence there is still room for improvement on the conventional slide rail locking device.

### SUMMARY

Therefore, an object of the disclosure is to provide a slide rail locking device that can alleviate at least one of the drawbacks of the prior art.

According to the disclosure, the slide rail locking device is adapted to be disposed on a slide rail that includes an outer rail and an inner rail which is movable relative to the outer rail. The slide rail locking device includes a base unit and a locking unit. The base unit includes an outer frame that is adapted to be fixedly connected to the outer rail, a base that is adapted to be fixedly connected to the inner rail, and an inner support frame that is fixedly connected to the base. The outer frame has an outer connecting portion that is adapted to be fixedly connected to the outer rail, and an engaging portion that extends from the outer connecting portion in a direction away from the outer rail. The base has a strength that is greater than a strength of the inner rail. The inner support frame and the base cooperatively define a moving slot. The locking unit includes a locking member that is rotatably connected to the base, a driving member that is connected to the locking member and that is movably disposed in the moving slot, and a resilient member that is connected to the base and the locking member. The locking member has a locking portion that separably engages the engaging portion of the outer frame. The driving member is operable to move along the moving slot to urge the locking member to rotate such that the locking portion of the locking member is disengaged from the engaging portion of the outer frame, thereby allowing the inner rail, the base, and the inner support frame to move relative to the outer rail.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a fragmentary perspective view illustrating that a first embodiment of a slide rail locking device according to the present disclosure is disposed on a slide rail.

FIG. 2 is a fragmentary, partly exploded perspective view of an assembly of the first embodiment and the slide rail.

FIG. 3 is an exploded perspective view of the first embodiment.

FIG. 4 is an exploded perspective view of the first embodiment taken from another angle.

FIG. 5 is a rear view of an inner support frame of a base unit of the first embodiment.

FIG. 6 is a rear view of the first embodiment, illustrating a locking portion of a locking member of a locking unit of the first embodiment engaging an engaging section of an engaging portion of an outer frame of the first embodiment.

FIG. 7 is a view similar to FIG. 6, but illustrating that the locking member is urged by a driving member of the first embodiment to rotate such that the locking portion of the locking member is moved downwardly.

FIG. 8 is a view similar to FIG. 7, but illustrating that the locking member is rotated to a position in which the locking portion of the locking member is disengaged from the engaging section of the engaging portion of the outer frame.

FIG. 9 is an exploded perspective view of a second embodiment of the slide rail locking device.

FIG. 10 is an exploded perspective view of the second embodiment taken from another angle.

FIG. 11 is a rear view of the second embodiment, illustrating a locking portion of a locking member of a locking unit of the second embodiment engaging an engaging section of an engaging portion of an outer frame of the second embodiment.

FIG. 12 a view similar to FIG. 11, but illustrating that the locking member is rotated to a position in which the locking portion of the locking member is disengaged from the engaging section of the engaging portion of the outer frame.

FIG. 13 is a view similar to FIG. 12, but illustrating that the locking member abuts against a guiding surface of the engaging section of the engaging portion of the outer frame.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

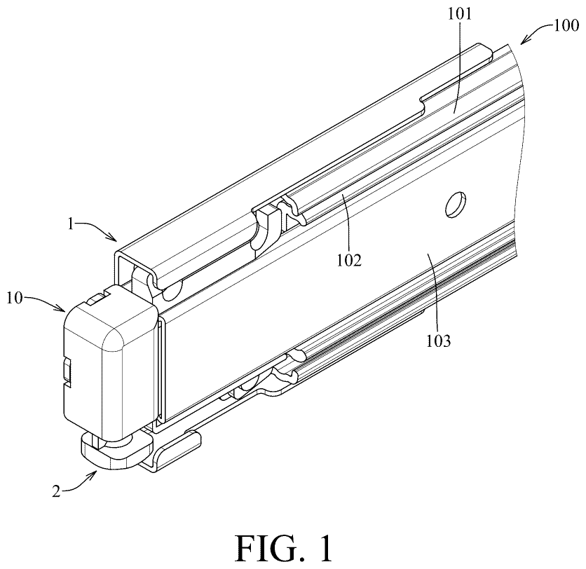

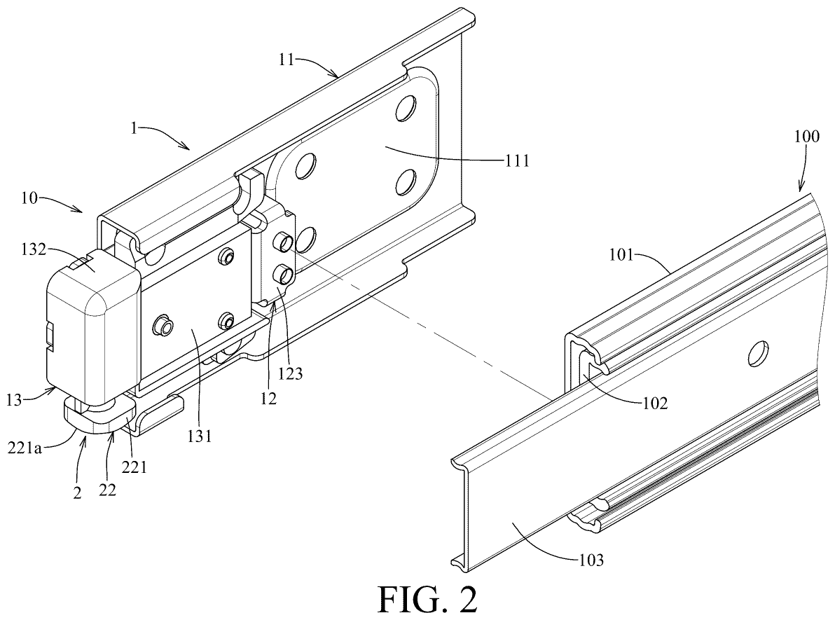

Referring to FIGS. 1 and 2, a first embodiment of a slide rail locking device 10 according to the present disclosure is adapted to be disposed on a slide rail 100. The slide rail 100 is disposed on a server rack cabinet (not shown), and includes an outer rail 101, a middle rail 102 that is movably disposed on the outer rail 101, and an inner rail 103 that is movably disposed on the middle rail 102 and that is movable relative to the outer rail 101 and the middle rail 102. The outer rail 101 is fixedly connected to the server rack cabinet (not shown). The inner rail 103 is fixedly connected to a server (not shown). The slide rail locking device 10 includes a base unit 1 and a locking unit 2.

Referring to FIGS. 2 to 4, the base unit 1 includes an outer frame 11 that is adapted to be fixedly connected to the outer rail 101, a base 12 that is adapted to be fixedly connected to the inner rail 103, and an inner support frame 13 that is fixedly connected to the base 12. The outer frame 11 has an outer connecting portion 111 that is adapted to be fixedly connected to the outer rail 101, and an engaging portion 112 that extends from the outer connecting portion 111 in a direction away from the outer rail 101. The engaging portion 112 has an upper plate section 112a that is connected to the outer connecting portion 111, an engaging section 112b that extends downwardly from the upper plate section 112a and that is spaced apart from the outer connecting portion 111, and a lower plate section 112c that is connected to the outer connecting portion 111 and that is spaced apart and located below the upper plate section 112a. The upper plate section 112a cooperates with the engaging section 112b and the lower plate section 112c to define a plate slot 113. The plate slot 113 has a first slot part 113a that is defined by the engaging section 112b and the lower plate section 112c, and a second slot part 113b that is defined by the upper plate section 112a and the lower plate section 112c. The first slot part 113a is in spatial communication with the second slot part 113b. A width of the first slot part 113a in an up-down direction is smaller than a width of the second slot part 113b in the up-down direction.

The base 12 has a strength that is greater than a strength of the inner rail 103. The strength means yield strength, that is to say, when a same external force is applied to the base 12 and the inner rail 103, plastic deformation is more unlikely to occur on the base 12 than on the inner rail 103. The base 12 has a base plate portion 121, a guiding portion 122 that is connected to one side of the base plate portion 121 which is distal from the outer rail 101, and an inner connecting portion 123 that is connected to another side of the base plate portion 121 which is proximate to the outer rail 101. The base plate portion 121 is formed with a plate opening 121a. A surface of the guiding portion 122 of the base 12 that faces the inner support frame 13 is formed with a guiding groove 122a that extends in the up-down direction. In one embodiment, the guiding groove 122a extends through the guiding portion 122. The inner connecting portion 123 of the base 12 is adapted to be fixedly connected to the inner rail 103.

Referring to FIGS. 2 to 5, the inner support frame 13 includes a cover portion 131 that is connected to the base plate portion 121, and a moving portion 132 that is connected to the cover portion 131. The cover portion 131 is connected to the base plate portion 121 by, but not limited by, three fastening members 14. The cover portion 131 is formed with an accommodating groove 131a. The moving portion 132 has a base wall 132a, and a surrounding wall 132b that extends from the base wall 132a toward the guiding portion 122 of the base 12. A surface of the base wall 132a that faces the base 12 is formed with a guiding rib 132a1 that extends in the up-down direction. The surrounding wall 132b is formed with a communication opening 132c that is in spatial communication with the accommodating groove 131a. The base wall 132a cooperates with the surrounding wall 132b and the guiding portion 122 of the base 12 to define a moving slot 132d that opens downwardly.

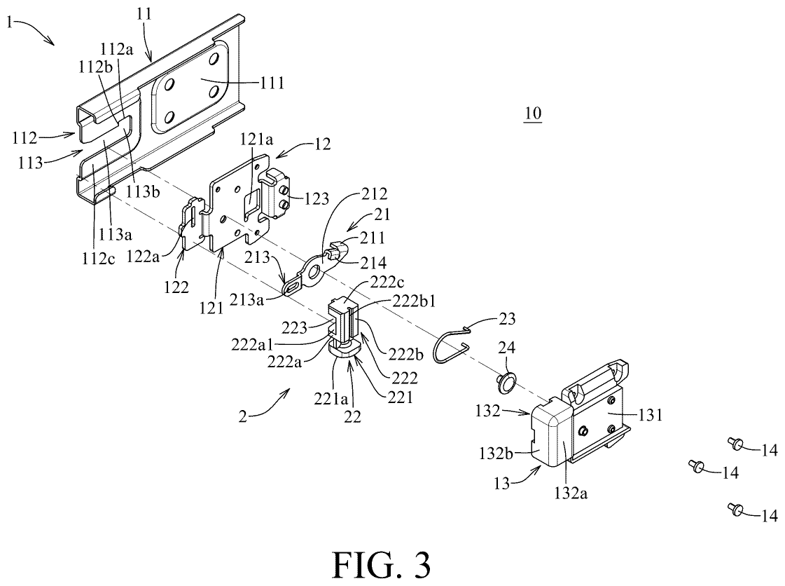

Referring to FIGS. 3, 4, and 6, the locking unit 2 includes a locking member 21 that is rotatably connected to the base plate portion 121 of the base 12, a driving member 22 that is connected to the locking member 21 and that is movably disposed in the moving slot 132d, a resilient member 23 that is connected to the base 12 and the locking member 21, and a connecting member 24 that connects the locking member 21 to the base 12. The locking member 21 is accommodated in the accommodating groove 131a, and has a locking portion 211 that extends through the plate opening 121a to separably engage the engaging in section 112b of the engaging portion 112 of the outer frame 11 and that is movably disposed in the second slot part 113b, a rotation portion 212 that is rotatably disposed on the base 12 and that is connected to the locking portion 211, a linking portion 213 that is connected to the rotation portion 212 and that extends through the communication opening 132c to be connected to the driving member 22, and a 10 positioning portion 214 that extends from the rotation portion 212 toward the inner support frame 13 and then bends downwardly. The rotation portion 212 is rotatably connected to the base plate portion 121 by the connecting member 24. The linking portion 213 is formed with an elongated linking slot 213a. The positioning portion 214 and the rotation portion 212 of the locking member 21 cooperatively position a portion of the resilient member 23 to prevent the resilient member 23 from being separated from the locking member 21.

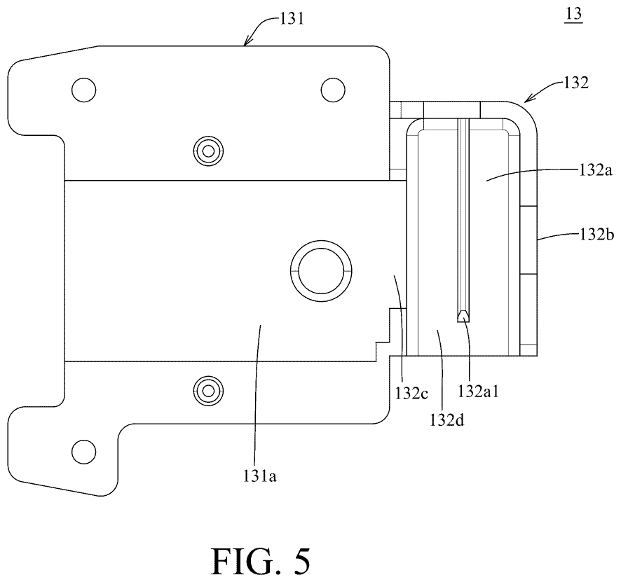

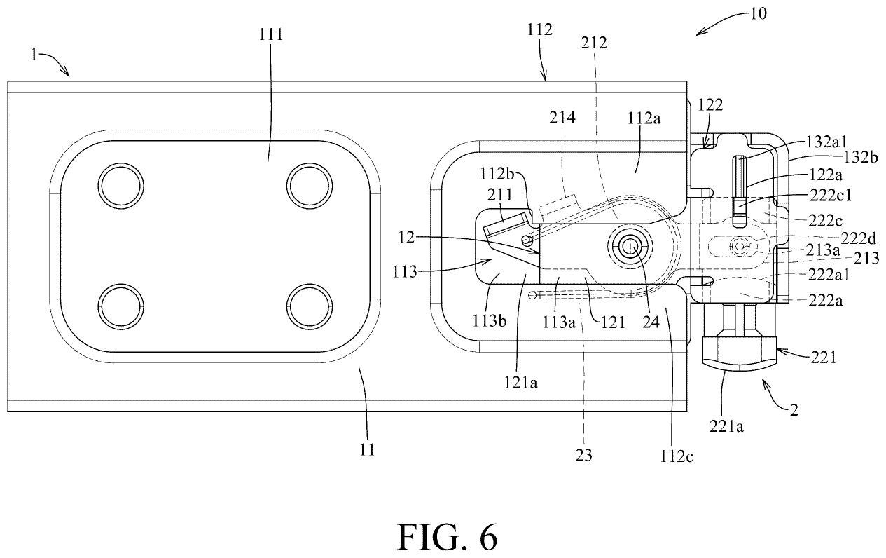

The driving member 22 is substantially in a shape of a square column, and has an operating portion 221 and a driving portion 222 that is connected to the operating portion 221. The operating portion 221 is formed with an operating surface 221a that protrudes downwardly and that is arc-shaped. The driving portion 222 has a bottom wall 222a that is connected to the operating portion 221, a side wall 222b that extends from the bottom wall 222a in a direction away from the operating portion 221, and a top wall 222c that is connected to the side wall 222b and that is spaced apart from the bottom wall 222a. The driving portion 222 defines a receiving groove 223 that receives the linking portion 213 of the locking member 21. The bottom wall 222a of the driving portion 222 is formed with an arc-shaped surface 222a1 that protrudes toward the top wall 222c of the driving portion 222. The side wall 222b of the driving member 22 is formed with a linking protrusion 222d that is movably disposed on the linking slot 213a. A surface of the side wall 222b of the driving member 22 that faces the base wall 132a of the inner support frame 13 is formed with a guiding slot 222b1 that extends in the up-down direction. The guiding rib 132a1 of the base wall 132a of the inner support frame 13 (see FIGS. 5 and 6) extends into the guiding slot 222b1. The surface of the guiding portion 122 of the base 12 that faces the inner support frame 13 and that is formed with the guiding groove 122a faces the driving member 22. The top wall 222c of the driving portion 222 of the driving member 22 is formed with a guiding block 222c1 that extends in the up-down direction and into the guiding groove 122a. By virtue of the guiding rib 132a1 (see FIGS. 5 and 6) extending into the guiding slot 222b1, and by virtue of the guiding block 222c1 extending into the guiding groove 122a, the driving member 22 is guided to smoothly move in the up-down direction in the moving slot 132d.

The resilient member 23 is a torsion spring, and has one end that is fixedly connected to the rotation portion 212 of the locking member 21, and another end that is fixedly connected to the base 12. The one end of the resilient member 23 that is fixedly connected to the rotation portion 212 is positioned by the rotation portion 212 and the positioning portion 214 of the locking member 21 (i.e., the portion of the resilient member 23 that is positioned by the rotation portion 212 and the positioning portion 214 of the locking member 21 has the one end).

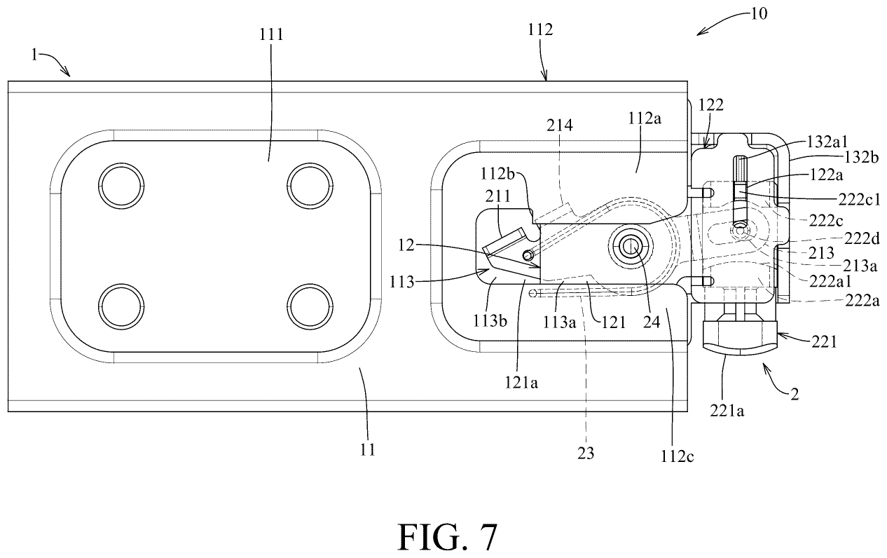

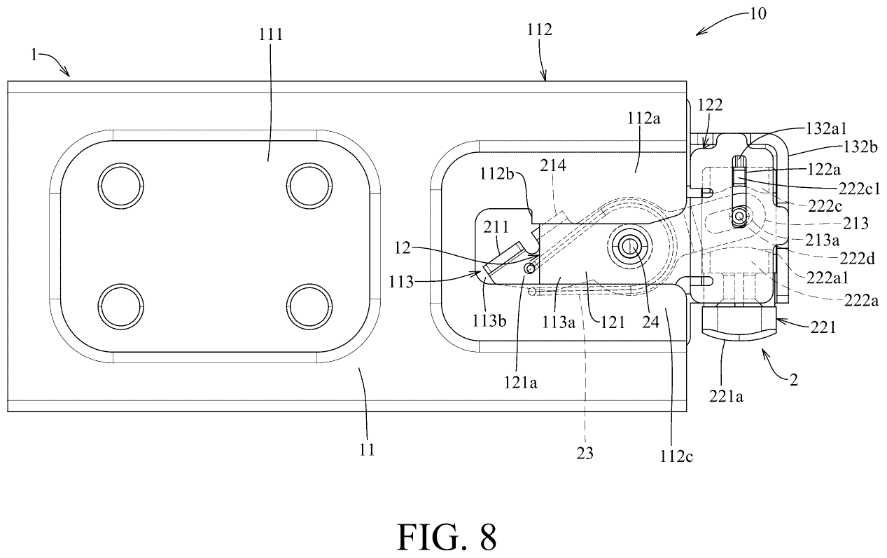

Referring to FIGS. 1, and 6 to 8, an operating process of the first embodiment of the slide rail locking device 10 is described below. As shown in FIG. 6, when the driving member 22 is not operated, the locking portion 211 of the locking member 21 engages the engaging section 112b of the engaging portion 112 of the outer frame 11 so that the inner rail 103 is prevented from sliding out of the outer rail 101. Next, when an external object (not shown) is moved toward the driving member 22 in a longitudinal direction of the slide rail 100 and abuts against the operating surface 221a, because the operating surface 221a protrudes downwardly and is arc-shaped, the external object pushes the driving member 22 upwardly as the external object keeps moving in the longitudinal direction of the slide rail 100. Thus, the driving member 22 is operable to move upwardly along the moving slot 132d. By virtue of the linking protrusion 222d of the driving portion 222 of the driving member 22 being movably disposed on the linking slot 213a, the linking protrusion 222d urges the linking portion 213 of the locking member 21 to move upwardly when the driving member 22 moves upwardly along the moving slot 132d, thereby urging the locking member 21 to rotate. Consequently, the locking portion 211 of the locking member 21 moves downwardly in the second slot part 113b such that the locking portion 211 is disengaged from the engaging portion 112 of the outer frame 11, as shown in FIGS. 7 and 8. The inner rail 103, the base 12, and the inner support frame 13 are allowed to move relative to the outer rail 101 after the locking portion 211 is disengaged from the engaging section 112b of the engaging portion 112. When the locking portion 211 is disengaged from the engaging portion 112 and when the inner rail 103, the base 12, and the inner support frame 13 are moved relative to the outer rail 101, the locking portion 211 moves past the first slot part 113 and is separated from the outer frame 11 so that the server (not shown) that is fixedly connected to the inner rail 103 may be removed from the server rack cabinet (not shown) for maintenance. It should be noted that, through configurations in which the driving member 22 urges the linking portion 213 of the locking member 21 to move upwardly via movement of the linking protrusion 222d of the driving portion 222 of the driving member 22 in the linking slot 213a, fit tolerance between the locking member 21 and the driving member 22 is increased. Because the linking slot 213a is elongated, even if locking members that are mass-produced are of unequal size, by virtue of the linking protrusion 222d being movably disposed on the elongated linking slot 213a, the driving member 22 may still urge the linking portion 213 to move upwardly, thereby urging any one of the locking members that are of unequal size to rotate. By virtue of the arc-shaped surface 222a1 of the bottom wall 222a protruding toward the top wall 222c and being arc-shaped, the bottom wall 222a does not interfere with movement of the linking portion 213 when the driving member 22 moves upwardly.

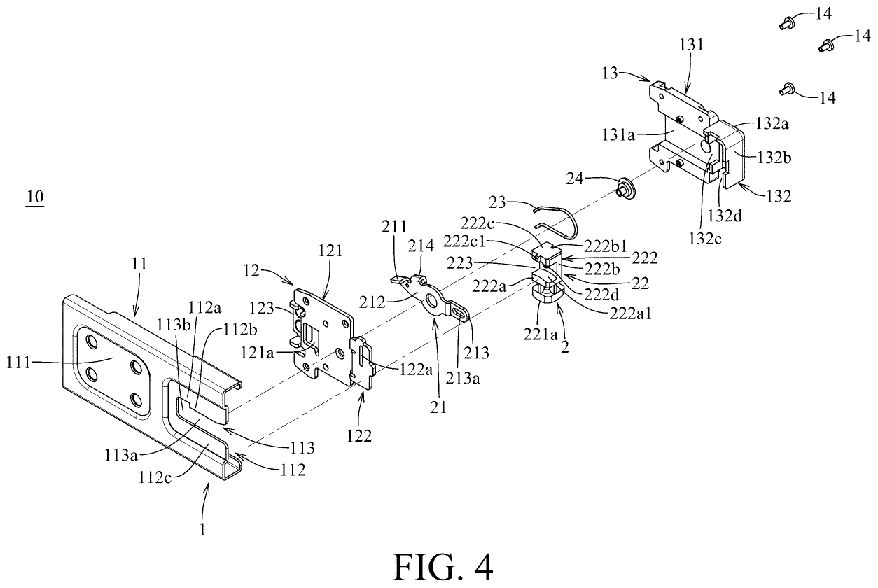

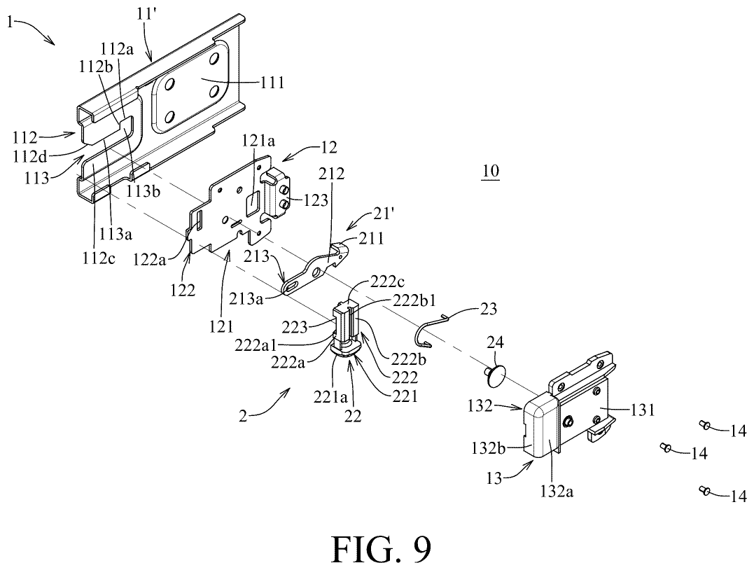

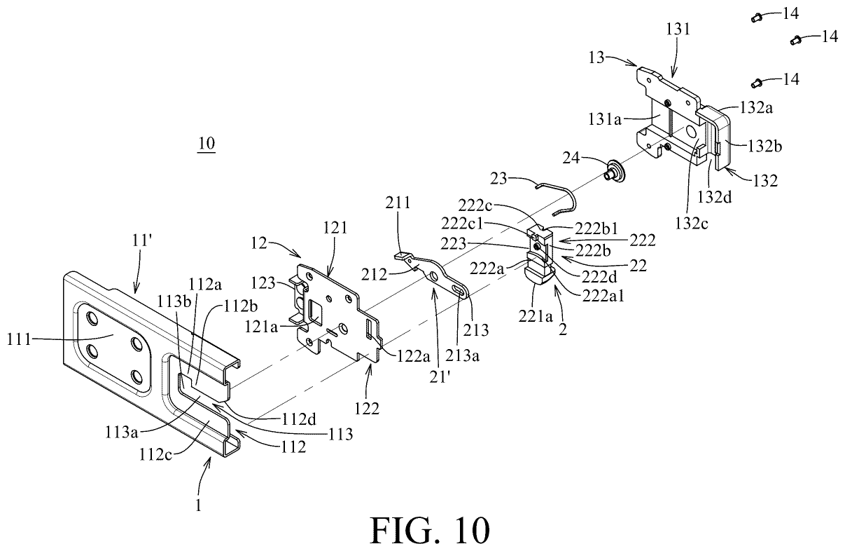

Referring to FIGS. 9 and 10, a second embodiment of the slide rail locking device 10 according to the present disclosure is generally similar to the first embodiment, but includes differences lying in the outer frame 11′ and the locking member 21′. Specifically, the engaging section 112b of the engaging portion 112 of the outer frame 11′ of the second embodiment has a guiding surface 112d that is inclined with respect to the up-down direction and that is adjacent to an opening of the first slot part 113a of the plate slot 113. The positioning portion 214 (see FIGS. 3 and 4) is omitted in the second embodiment.

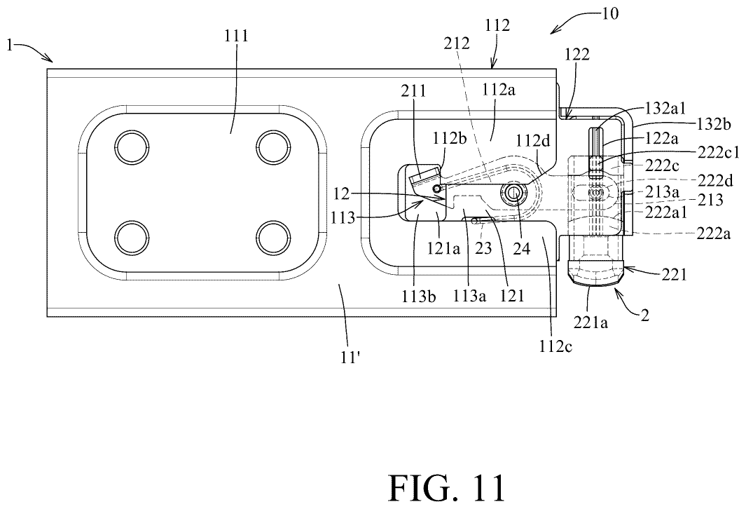

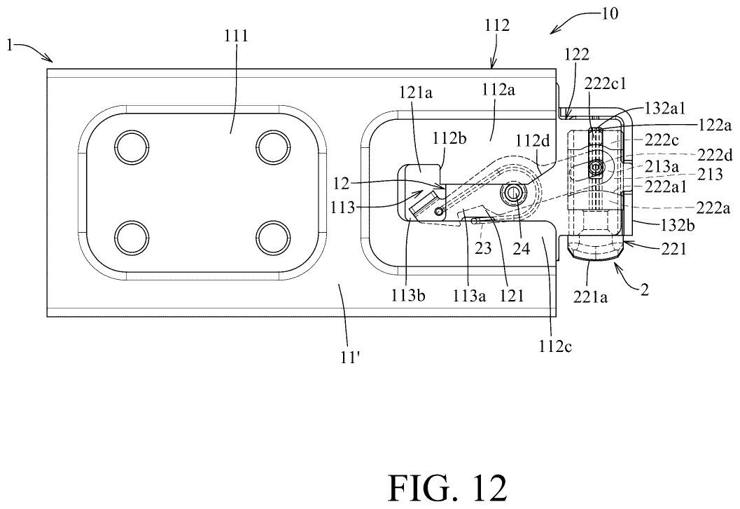

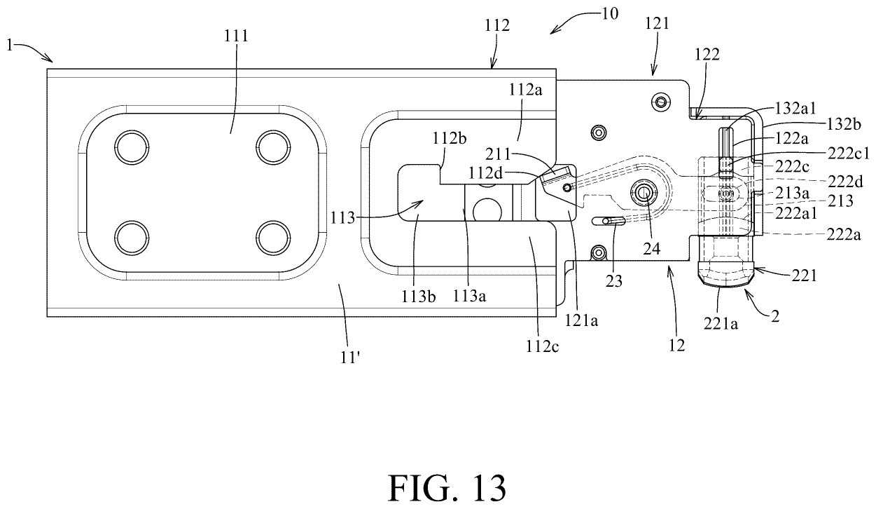

Referring to FIGS. 1 and 11 to 13, an operating process of the second embodiment of the slide rail locking device 10 is substantially similar to that of the first embodiment. As shown in FIG. 11, when the driving member 22 is not operated, the locking portion 211 of the locking member 21′ engages the engaging section 112b of the engaging portion 112 of the outer frame 11′ so that the inner rail 103 is prevented from sliding out of the outer rail 101. Next, when an external object (not shown) is moved toward the driving member 22 in the longitudinal direction of the slide rail 100 and abuts against the operating surface 221a, because the operating surface 221a protrudes downwardly and is arc-shaped, the external object pushes the driving member 22 upwardly as the external object keeps moving in the longitudinal direction of the slide rail 100. Thus, the driving member 22 is operable to move upwardly along the moving slot 132d. By virtue of the linking protrusion 222d of the driving portion 222 of the driving member 22 being movably disposed on the linking slot 213a, the linking protrusion 222d urges the linking portion 213 of the locking member 21′ to move upwardly when the driving member 22 moves upwardly along the moving slot 132d, thereby urging the locking member 21′ to rotate. Consequently, the locking portion 211 of the locking member 21′ moves downwardly in the second slot part 113b such that the locking portion 211 is disengaged from the engaging portion 112 of the outer frame 11′, as shown in FIG. 12. The inner rail 103, the base 12, and the inner support frame 13 are allowed to move relative to the outer rail 101 after the locking portion 211 is disengaged from the engaging section 112b of the engaging portion 112. When the locking portion 211 is disengaged from the engaging portion 112 and when the inner rail 103, the base 12, and the inner support frame 13 are moved relative to the outer rail 101, the locking portion 211 moves past the first slot part 113 and is separated from the outer frame 11′ so that the server (not shown) that is fixedly connected to the inner rail 103 may be removed from the server rack cabinet (not shown) for the maintenance. After the maintenance, the server is fixedly connected to the inner rail 103 again, and then the inner rail 103, the base 12, and the inner support frame 13 are urged to move relative to the outer rail 101 in an opposite direction such that the locking portion 211 of the locking member 21′ abuts against the guiding surface 112d. By virtue of the inclined guiding surface 112d, when the inner rail 103, the base 12, and the inner support frame 13 are kept moving toward the second slot part 113b of the plate slot 113, the locking member 21′ is urged to rotate. Consequently, the locking portion 211 of the locking member 21′ moves downwardly along the guiding surface 112d and enters the first slot part 113a of the plate slot 113. Afterward, the locking portion 211 of the locking member 21′ is moved back to the second slot part 113b and engages the engaging portion 112 of the outer frame 11′ again. By virtue of the inclined guiding surface 112d, a user of the slide rail locking device may not need to urge the driving member 22 to move upwardly for rotating the locking member 21′ and urging the locking portion 211 to enter the second slot part 113b of the plate slot 113. Thus, the slide rail locking device may be more user-friendly,

In summary, by virtue of the locking member 21, 21′ of the slide rail locking device 10 being rotatably connected to the base 12 that has the greater strength instead of being rotatably connected to the inner rail 103, when the plastic deformation occurs on the inner rail 103, the locking member 21, 21′ is still able to rotate smoothly or to engage the engaging portion 112 of the outer frame 11, 11′. Thus, the purpose of the disclosure is indeed achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A slide rail locking device adapted to be disposed on a slide rail that includes an outer rail and an inner rail which is movable relative to the outer rail, the slide rail locking device comprising:
a base unit including an outer frame that is adapted to be fixedly connected to the outer rail, a base that is adapted to be fixedly connected to the inner rail, and an inner support frame that is fixedly connected to the base, the outer frame having an outer connecting portion that is adapted to be fixedly connected to the outer rail, and an engaging portion that extends from the outer connecting portion in a direction away from the outer rail, the base having a strength that is greater than a strength of the inner rail, the inner support frame and the base cooperatively defining a moving slot; and
a locking unit including a locking member that is rotatably connected to the base, a driving member that is connected to the locking member and that is movably disposed in the moving slot, and a resilient member that is connected to the base and the locking member, the locking member having a locking portion that separably engages the engaging portion of the outer frame, the driving member being operable to move along the moving slot to urge the locking member to rotate such that the locking portion of the locking member is disengaged from the engaging portion of the outer frame, thereby allowing the inner rail, the base, and the inner support frame to move relative to the outer rail.

2. The slide rail locking device as claimed in claim 1, wherein the locking member further has a rotation portion that is rotatably disposed on the base and that is connected to the locking portion, and a linking portion that is connected to the rotation portion and the driving member.

3. The slide rail locking device as claimed in claim 2, wherein the driving member has an operating portion and a driving portion that is connected to the operating portion, the driving portion having a bottom wall that is connected to the operating portion, a side wall that extends from the bottom wall in a direction away from the operating portion, and a top wall that is connected to the side wall and that is spaced apart from the bottom wall, the driving portion defining a receiving groove that receives the linking portion of the locking member.

4. The slide rail locking device as claimed in claim 3, wherein the linking portion of the locking member is formed with an elongated linking slot, and the side wall of the driving member is formed with a linking protrusion that is movably disposed on the linking slot.

5. The slide rail locking device as claimed in claim 3, wherein the base has a base plate portion that is rotatably connected to the locking member, a guiding portion that is connected to one side of the base plate portion which is distal from the outer rail, and an inner connecting portion that is connected to another side of the base plate portion which is proximate to the outer rail, the base plate portion being formed with a plate opening through which the locking portion of the locking member extends and engages the engaging portion of the outer frame, the guiding portion and the inner support frame cooperatively defining the moving slot, the inner connecting portion of the base being adapted to be fixedly connected to the inner rail.

6. The slide rail locking device as claimed in claim 5, wherein the inner support frame includes a cover portion that is connected to the base plate portion, and a moving portion that is connected to the cover portion, the cover portion being formed with an accommodating groove that accommodates the locking member, the moving portion having a base wall, and a surrounding wall that extends from the base wall toward the guiding portion of the base, the surrounding wall being formed with a communication opening that is in spatial communication with the accommodating groove, the base wall cooperating with the surrounding wall and the guiding portion of the base to define the moving slot, the linking portion of the locking member extending through the communication opening.

7. The slide rail locking device as claimed in claim 6, wherein a surface of the side wall of the driving member that faces the base wall of the inner support frame is formed with a guiding slot that extends in an up-down direction, the base wall of the inner support frame being formed with a guiding rib that extends in the up-down direction and into the guiding slot.

8. The slide rail locking device as claimed in claim 6, wherein a surface of the guiding portion of the base that faces the driving member is formed with a guiding groove that extends in an up-down direction, and the top wall of the driving portion of the driving member is formed with a guiding block that extends in the up-down direction and into the guiding groove.

9. The slide rail locking device as claimed in claim 3, wherein the bottom wall of the driving portion of the driving member is formed with an arc-shaped surface that protrudes toward the top wall of the driving portion, the operating portion of the driving member being formed with an operating surface that protrudes downwardly and that is arc-shaped.

10. The slide rail locking device as claimed in claim 2, wherein the resilient member is a torsion spring, and has one end that is fixedly connected to the rotation portion of the locking member, and another end that is fixedly connected to the base, the locking member further having a positioning portion that extends from the rotation portion toward the inner support frame and then bends downwardly, the positioning portion and the rotation portion of the locking member cooperatively positioning a portion of the resilient member.

11. The slide rail locking device as claimed in claim 1, wherein the engaging portion of the outer frame has an upper plate section that is connected to the outer connecting portion, and an engaging section that extends downwardly from the upper plate section and that is spaced apart from the outer connecting portion, the locking portion of the locking member separably engages the engaging section.

12. The slide rail locking device as claimed in claim 11, wherein the engaging portion of the outer frame further has a lower plate section that is connected to the outer connecting portion and that is spaced apart from and located below the upper plate section, the upper plate section cooperating with the engaging section and the lower plate section to define a plate slot, the plate slot having a first slot part that is defined by the engaging section and the lower plate section, and a second slot part that is defined by the upper plate section and the lower plate section, the first slot part being in spatial communication with the second slot part, a width of the first slot part in an up-down direction being smaller than a width of the second slot part in the up-down direction, the locking portion of the locking member being movably disposed in the second slot part, the locking portion of the locking member being operable to move past the first slot part and to be separated from the outer frame when the locking portion is disengaged from the engaging portion of the outer frame and when the inner rail, the base, and the inner support frame are moved relative to the outer rail.

13. The slide rail locking device as claimed in claim 12, wherein the engaging section of the engaging portion of the outer frame has a guiding surface that is inclined with respect to the up-down direction and that is adjacent to an opening of the first slot part of the plate slot.
